(19) United States
(12) Patent Application Publication
(10) Pub. No.: US 2025/0098369 A1
(43) Pub. Date: Mar. 20, 2025

(54) DISPLAY DEVICE AND METHOD OF MANUFACTURING DISPLAY DEVICE

(71) Applicant: Samsung Display Co., LTD., Yongin-si (KR)

(72) Inventors: Dal Rae JIN, Yongin-si (KR); Seul Ki KIM, Yongin-si (KR)

(73) Assignee: Samsung Display Co., LTD., Yongin-si (KR)

(21) Appl. No.: 18/734,281

(22) Filed: Jun. 5, 2024

(30) Foreign Application Priority Data
Sep. 20, 2023 (KR) 10-2023-0125355

(51) Int. Cl. H01L 33/10; H01L 25/075; H01L 25/16; H01L 33/50; H01L 33/62

(52) U.S. Cl. CPC H10H 20/814; H01L 25/0753; H01L 25/167; H10H 20/8512; H10H 20/857; H10H 20/0361

(57) ABSTRACT

A display device and a method of manufacturing the display device, the display device may include a sub-pixel portion disposed on a base layer and may include a light emitting element area where a light emitting element may be disposed and a sub-pixel area. The light emitting element area and the sub-pixel area may not overlap each other in a plan view.

### CROSS-REFERENCE TO RELATED APPLICATIONS

This application claims priority under 35 U.S.C. § 119 from Korean Patent Application No. 10-2023-0125355 filed on Sep. 20, 2023 in the Korean Intellectual Property Office, the entire contents of which are incorporated herein by reference.

### BACKGROUND

### 1. Technical Field

The disclosure relates to a display device and a method of manufacturing the display device.

### 2. Description of the Related Art

Recently, as interest in information display increases, research and development on a display device is continuously being conducted. A display device may include a pixel including a light emitting element.

As an application field of the display device further expands, a size of the light emitting element applied to the display device may decrease in order to implement a display device of high performance.

In case that the size of the light emitting element is decreased, difficulty of a manufacturing process may increase, and thus the process may be difficult to be properly performed. A concern that a process cost increases since an additional process is further required may exist.

### SUMMARY

An aspect of the disclosure is to provide a display device and a method of manufacturing the display device in which a process step may be simplified and thus a process cost may be reduced.

An aspect of the disclosure is to provide a display device and a method of manufacturing the display device in which the area of an emission area in which a light emitting element emits light may expand.

According to an embodiment of the disclosure, a display device may include a sub-pixel portion disposed on a base layer that may include a light emitting element area where a light emitting element may be disposed and a sub-pixel area. The light emitting element area and the sub-pixel area may not overlap each other in a plan view.

In an embodiment, the light emitting element area may be a non-sub-pixel area where light of a color may not be visible.

In an embodiment, the light emitting element area and the sub-pixel area may be arranged alternately along a direction.

In an embodiment, the sub-pixel portion may have a rectangular shape that may include a long side and a short side in a plan view.

In an embodiment, the display device may further include a first reflective layer covering at least a portion of the light emitting element and exposing a side portion of the light emitting element. The first reflective layer may overlap the light emitting element area in a plan view.

In an embodiment, the side portion of the light emitting element exposed by the first reflective layer may face the sub-pixel area.

In an embodiment, the first reflective layer may include a plurality of protrusions and a body portion that are integral with each other, each of the plurality of protrusions may form a protruding structure that may protrude from the body portion.

In an embodiment, the display device may further include a pixel circuit layer including the base layer and a pixel circuit disposed on the base layer, and an element base disposed on the pixel circuit layer, the element base may form a base on which the light emitting element may be disposed, the element base may include a contact portion.

In an embodiment, the first reflective layer may be electrically connected to the light emitting element and may be electrically connected to the pixel circuit through the contact portion.

In an embodiment, the display device may further include a second reflective layer disposed in the sub-pixel area, the second reflective layer may not overlap the light emitting element in a plan view.

In an embodiment, the second reflective layer may include a reflective surface facing a light output direction of the display device.

In an embodiment, the display device may further include a color conversion layer disposed on the second reflective layer in the sub-pixel area and may include a quantum-dot. The color conversion layer may be adjacent to the light emitting element in a planar direction.

In an embodiment, the display device may further include a light blocking layer disposed on the light emitting element, and the light blocking layer may not overlap the sub-pixel area.

In an embodiment, the sub-pixel portion may include a first sub-pixel portion and a second sub-pixel portion disposed adjacent to each other in a planar direction. Each of the first sub-pixel portion and the second sub-pixel portion may include a first reflective layer covering at least a side portion of the light emitting element, and a second reflective layer disposed in the sub-pixel area. Light emitted by the light emitting element included in the first sub-pixel portion may be guided in a light output direction of the display device by the first reflective layer of the first sub-pixel portion, the first reflective layer of the second sub-pixel portion, and the second reflective layer of the first sub-pixel portion.

In an embodiment, the sub-pixel portion may include a first sub-pixel portion emitting light of a first color, a second sub-pixel portion emitting light of a second color, and a third sub-pixel portion emitting light of a third color. A first color conversion layer including a first quantum-dot may be disposed in the sub-pixel area of the first sub-pixel portion. A second color conversion layer including a second quantum-dot may be disposed in the sub-pixel area of the second sub-pixel portion. A scattering layer including a scatterer may be disposed in the sub-pixel area of the third sub-pixel portion.

In an embodiment, the sub-pixel portion may include a first sub-pixel portion emitting light of a first color, a second sub-pixel portion emitting light of a second color, and a third sub-pixel portion emitting light of a third color. The light emitting element of the first sub-pixel portion may be a first light emitting element emitting the light of the first color. The light emitting element of the second sub-pixel portion may be a second light emitting element emitting the light of the second color. The light emitting element of the third sub-pixel portion may be a third light emitting element emitting the light of the third color. A scattering layer including a scatterer may be disposed in the sub-pixel area of each of the first sub-pixel portion, the second sub-pixel portion, and the third sub-pixel portion.

According to an embodiment of the disclosure, a display device may include a light emitting element disposed on a base layer and in a light emitting element area, a first reflective layer covering at least a portion of the light emitting element and exposing at least another portion of the light emitting element, a second reflective layer disposed in a sub-pixel area, the sub-pixel area may be adjacent to and in a planar direction from the light emitting element area, the second reflective layer may include a reflective surface facing a light output direction of the display device, and a color conversion layer may be disposed in the sub-pixel area, and the color conversion layer may include a quantum-dot and may overlap the second reflective layer in a plan view.

According to an embodiment of the disclosure, a method of manufacturing a display device may include manufacturing a light emitting element on an element base, and disposing the element base and the light emitting element on a pixel circuit layer. The manufacturing of the light emitting element may include patterning the light emitting element on the element base, patterning a first reflective layer covering a portion of the light emitting element and exposing at least another portion of the light emitting element, and patterning a second reflective layer in an area where the light emitting element may not be disposed.

In an embodiment, the element base may include a wafer for forming the light emitting element. The pixel circuit layer may include a pixel circuit. The disposing of the element base and the light emitting element on pixel circuit layer may include forming a contact portion through the element base to electrically connect the pixel circuit to the light emitting element.

In an embodiment, the method may further include forming a color conversion layer that may include a quantum-dot on the element base in an area where the light emitting element may not be disposed. The light emitting element and the first reflective layer may form a bank structure for the forming of the color conversion layer.

According to an embodiment of the disclosure, a display device and a method of manufacturing the display device in which a process step may be simplified and thus a process cost may be reduced may be provided.

According to an embodiment of the disclosure, a display device and a method of manufacturing the display device in which the area of an emission area in which a light emitting element emits light may be expanded may be provided.

### BRIEF DESCRIPTION OF THE DRAWINGS

The above and other features of the disclosure will become more apparent by describing in further detail embodiments thereof with reference to the accompanying drawings, in which:

FIG. 1 is a plan view illustrating a display device according to an embodiment;

FIGS. 2 and 3 are schematic plan views illustrating a display device according to an embodiment;

FIGS. 4 to 7 are schematic diagrams illustrating a display device according to an embodiment;

FIG. 8 is a schematic diagram illustrating a display device according to an embodiment;

FIGS. 9 and 10 are schematic diagrams illustrating a display device according to an embodiment;

FIG. 11 is a schematic diagram illustrating a display device according to an embodiment; and

FIGS. 12 to 25 are schematic diagrams for each process step illustrating a method of manufacturing a display device according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

The disclosure relates to a display device and a method of manufacturing the display device. Hereinafter, a display device and a method of manufacturing the display device according to an embodiment are described with reference to the accompanying drawings.

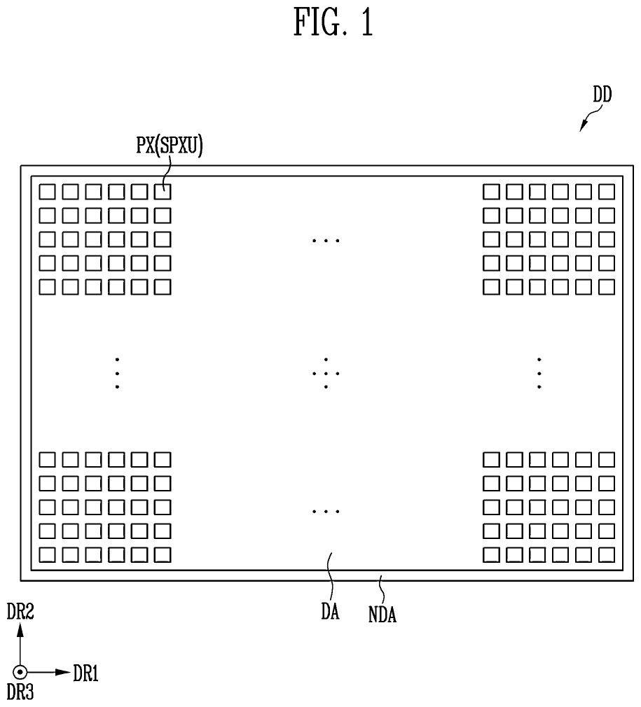

FIG. 1 is a plan view illustrating a display device according to an embodiment.

Referring to FIG. 1, the display device DD may be configured to output light information. For example, the display device DD may be a device for displaying a moving image or a still image, and may be applied to various devices. The display device DD may have a rectangular shape in a plan view having a long side along a first direction DR1 and a short side along a second direction DR2 intersecting the first direction DR1. A corner where the long side of the first direction DR1 and the short side of the second direction DR2 meet may be formed to be rounded to have a curvature (e.g., predetermined of selectable curvature) or may be formed to have a right angle. A planar shape of the display device DD may not be limited to a quadrangle, and may be formed in another polygon, circle, or ellipse. The display device DD may be formed to be approximately flat, but may not be limited thereto. For example, the display device DD may include a curved portion formed at left and right ends and having a constant curvature or a varying curvature. The display device DD may be flexibly formed to be crooked, curved, bent, folded, or rolled.

The display device DD may further include pixels PX, scan lines extending in the first direction DR1, and data lines extending in the second direction DR2 to display an image. The pixels PX may be arranged in a matrix shape in the first direction DR1 and the second direction DR2. However, the disclosure may not be limited thereto.

The display device DD may include a display area DA and a non-display area NDA. According to an embodiment, the non-display area NDA may be disposed around the display area DA. The non-display area NDA may surround at least a portion of the display area DA.

The pixel PX may be disposed in the display area DA. The pixel PX may not be disposed in the non-display area NDA. According to an embodiment, the pixel PX may include a sub-pixel portion SPXU.

The sub-pixel portion SPXU may be referred to as a sub-pixel member.

The sub-pixel portion SPXU may be referred to as a sub-pixel structure.

The sub-pixel portion SPXU may be referred to as a sub-pixel unit.

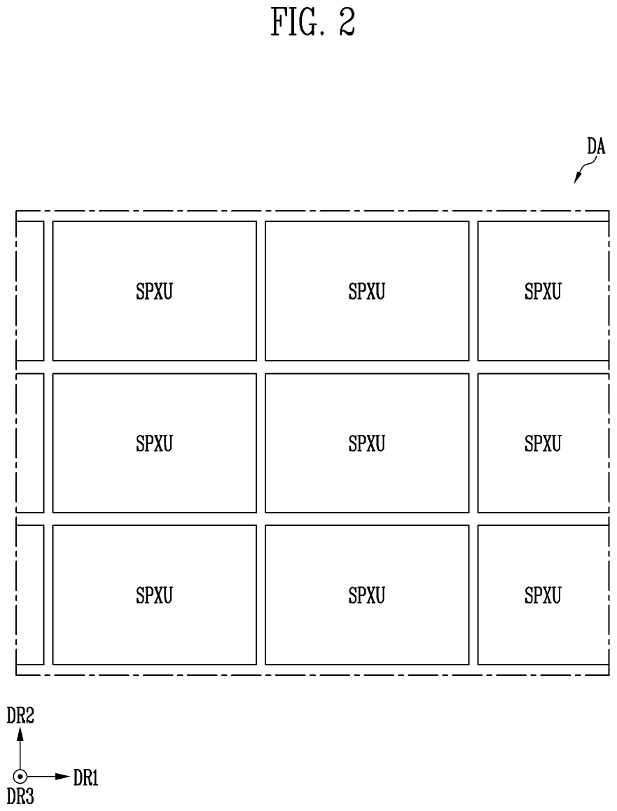

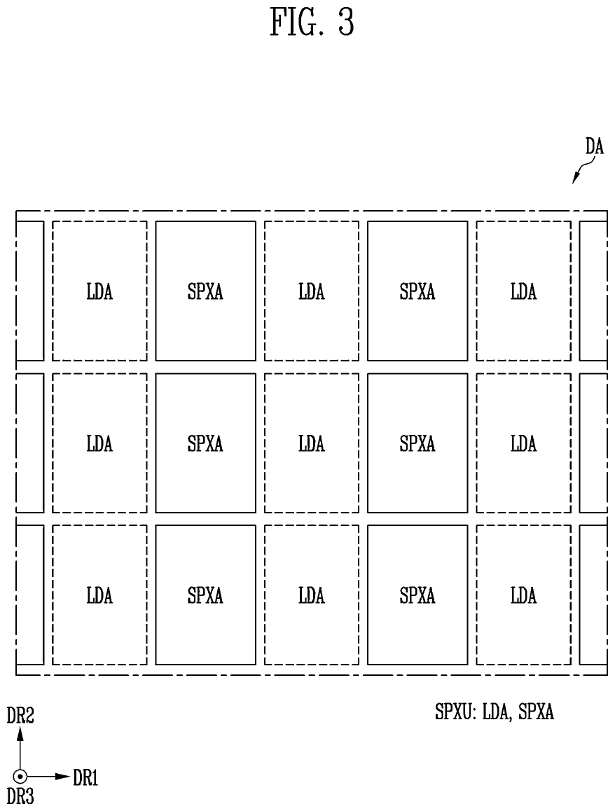

FIGS. 2 and 3 are schematic plan views illustrating a display device according to an embodiment. FIGS. 2 and 3 schematically show a display area DA and show a same area. A positional relationship of each of configurations will be clearly understood with reference to FIGS. 2 and 3.

Referring to FIGS. 1 to 3, a pixel PX according to an embodiment may include a sub-pixel portion SPXU. According to an embodiment, two or more sub-pixel portions SPXU may form the pixel PX (or a pixel unit).

For example, each of the pixels PX may include sub-pixel portions SPXU. According to an embodiment, the sub-pixel portions SPXU may include a first sub-pixel portion emitting light of a first color, a second sub-pixel portion emitting light of a second color, and a third sub-pixel portion emitting light of a third color.

According to an embodiment, the light of the first color may be light of a red wavelength band. The light of the second color may be light of a green wavelength band. The light of the third color may be light of a blue wavelength band. The red wavelength band may be in a range of about 600 nm to about 750 nm, the green wavelength band may be in a range of about 480 nm to about 560 nm, and the blue wavelength band may be in a range of about 370 nm to about 460 nm. However, the disclosure may not be limited thereto.

The sub-pixel portions SPXU may be arranged in various methods. For example, the sub-pixel portions SPXU may be arranged in a matrix structure based on the first direction DR1 and the second direction DR2. However, the disclosure may not be limited thereto. An arrangement structure of the sub-pixel portions SPXU may vary according to an arrangement structure of the pixels PX according to an embodiment.

The sub-pixel portion SPXU may have various shapes. For example, the sub-pixel portion SPXU may have a rectangular shape having a long side along the first direction DR1 and a short side along the second direction DR2. However, the disclosure may not be limited thereto.

According to an embodiment, in the sub-pixel portion SPXU, an area where a light emitting element LD may be disposed and an area where light of a color may be visible (or where light is emitted from the display) may be defined separately.

For example, the sub-pixel portion SPXU may include a light emitting element area LDA and a sub-pixel area SPXA. According to an embodiment, the light emitting element area LDA and the sub-pixel area SPXA may not overlap each other in a plan view. For example, the light emitting element area LDA and the sub-pixel area SPXA may be spaced apart from each other in the first direction DR1.

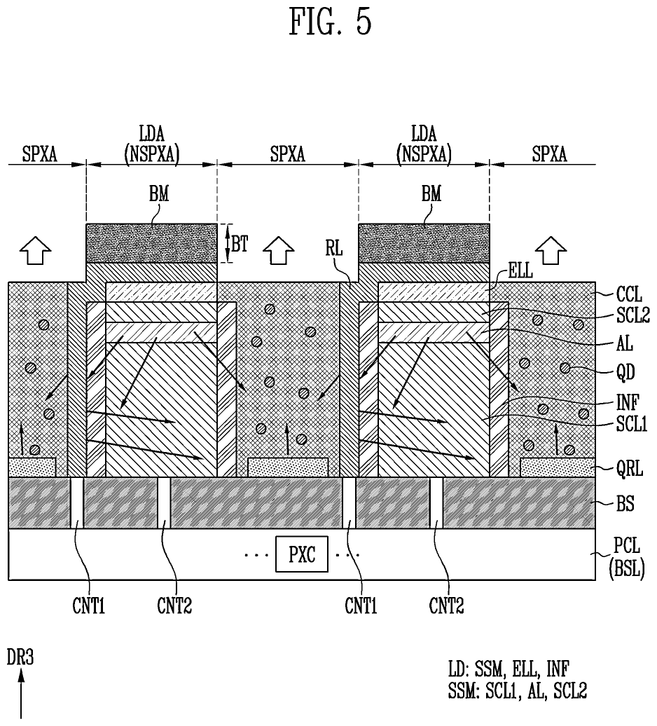

The light emitting element area LDA may be an area where the light emitting element LD (refer to FIG. 5) may be disposed. For example, the light emitting element LD may overlap the light emitting element area LDA in a plan view. The light emitting element area LDA may be an area where the light emitting element LD may be disposed, but light of a color may not be visible.

The sub-pixel area SPXA may be an area where the light emitting element LD may not be disposed. For example, the light emitting element LD may not overlap the sub-pixel area SPXA in a plan view. The sub-pixel area SPXA may be an area where light of a color may be visible. According to an embodiment, light of any one of each of the first color, the second color, and the third color may be provided in the sub-pixel area SPXA.

For example, the sub-pixel area SPXA may include a first sub-pixel area included in the first sub-pixel portion among the sub-pixel portions SPXU and emit light of the first color, a second sub-pixel area included in the second sub-pixel portion among the sub-pixel portions SPXU and emit light of the second color, and a third sub-pixel area included in the third sub-pixel portion among the sub-pixel portions SPXU and emit light of the third color.

According to an embodiment, the light emitting element areas LDA may be sequentially disposed along the second direction DR2. The sub-pixel areas SPXA may be sequentially disposed along the second direction DR2. The light emitting element areas LDA and the sub-pixel areas SPXA may be alternately disposed along the first direction DR1. However, the disclosure may not be limited thereto. According to an arrangement structure of the sub-pixel portions SPXU, an arrangement structure of the light emitting element areas LDA and the sub-pixel areas SPXA may be variously changed.

According to an embodiment, sizes of the light emitting element area LDA and the sub-pixel area SPXA may correspond to each other. For example, sizes of each of the light emitting element area LDA and the sub-pixel area SPXA may be substantially a same. However, the disclosure may not be limited thereto. For example, the size of the sub-pixel area SPXA may be greater than the size of the light emitting element area LDA so that the size of the sub-pixel area SPXA may be expanded.

According to an embodiment, shapes of the light emitting element area LDA and the sub-pixel area SPXA may correspond to each other. For example, the shapes of each of the light emitting element area LDA and the sub-pixel area SPXA may be substantially a same. However, the disclosure may not be limited thereto.

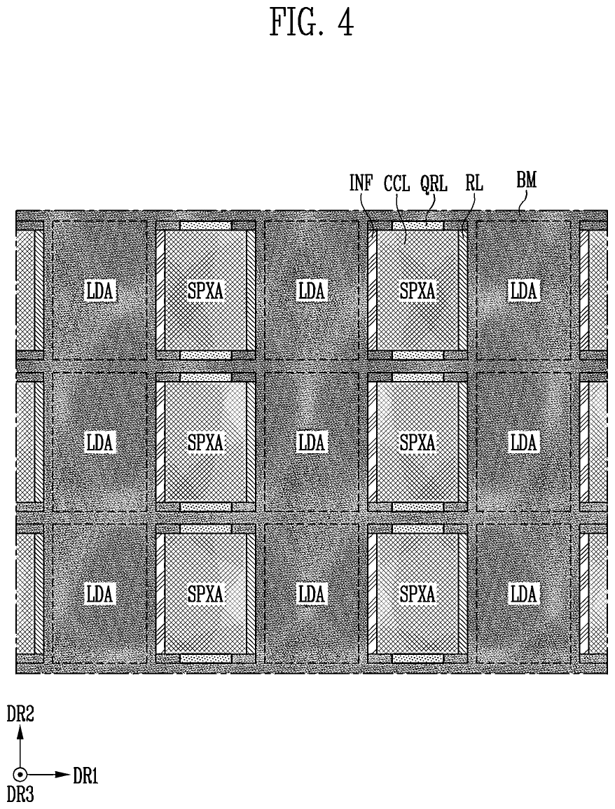

With reference to FIGS. 4 to 7, a display device DD according to an embodiment may be described.

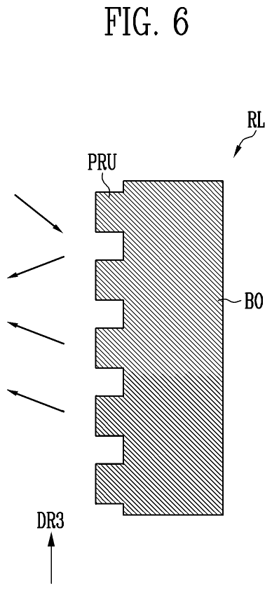

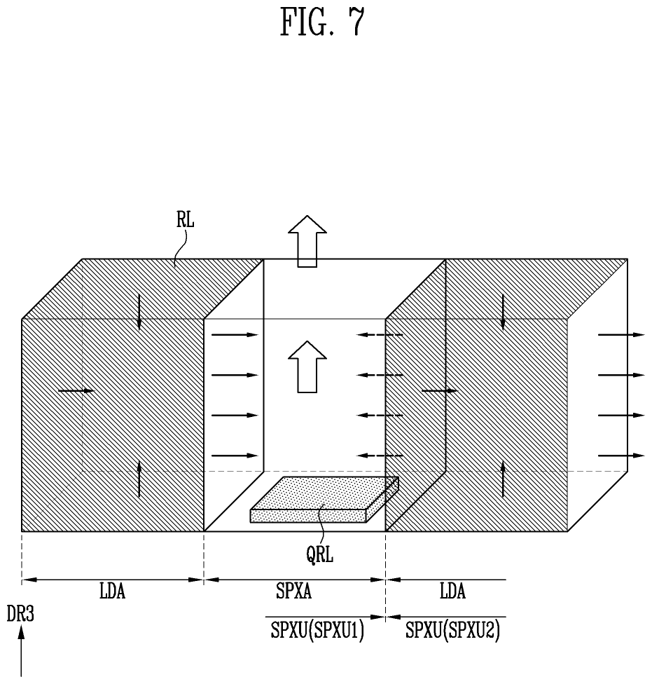

FIGS. 4 to 7 are schematic diagrams illustrating a display device according to an embodiment. FIG. 4 may show a same area as a planar structure described above with reference to FIGS. 2 and 3. With reference to FIGS. 2 to 4, a disposition relationship of each of configurations will be clearly understood. FIG. 5 may show a schematic cross-sectional structure of the display device DD according to an embodiment. FIG. 6 may show a surface structure of a first reflective layer RL. FIG. 7 may show an optical path structure in the display device DD according to an embodiment.

Referring to FIGS. 4 to 7, the display device DD may include a pixel circuit layer PCL, an element base BS, a first contact portion CNT1, a second contact portion CNT2, the light emitting element LD, the first reflective layer RL, a second reflective layer QRL, a color conversion layer CCL, and a light blocking layer BM.

The pixel circuit layer PCL may be a layer including a pixel circuit PXC for driving the light emitting elements LD. The pixel circuit layer PCL may include a base layer BSL, conductive layers for forming pixel circuits, and insulating layers disposed between the conductive layers.

The base layer BSL may form a base on which the pixel circuit PXC may be disposed. The base layer BSL may be a substrate or an insulating layer that may include various materials. For example, the base layer BSL may include a glass material. As another example, the base layer BSL may include polyimide. However, the disclosure may not be limited thereto.

The pixel circuit layer PCL may include a backplane substrate.

According to an embodiment, the pixel circuit PXC may include a thin film transistor, and may be electrically connected to the light emitting elements LD to provide an electrical signal for the light emitting elements LD to emit light.

The element base BS may be disposed on the pixel circuit layer PCL (for example, the base layer BSL). The element base BS may form a base on which the light emitting element LD and the color conversion layer CCL may be disposed.

The element base BS may be a wafer for forming for example, growing (e.g., epitaxially growing) the light emitting element LD. For example, the element base BS may include a sapphire substrate or a silicon material. However, the disclosure may not be limited to a specific example.

According to an embodiment, the element base BS provided for patterning the light emitting element LD may be disposed (for example, directly disposed) on the pixel circuit layer PCL (for example, the base layer BSL).

The first contact portion CNT1 and the second contact portion CNT2 may be formed on the element base BS. For example, the first contact portion CNT1 and the second contact portion CNT2 may pass through a portion of the element base BS.

The first contact portion CNT1 may include a conductive material and may be electrically connected to the first reflective layer RL1. The first contact portion CNT1 may electrically connect the pixel circuit PXC and the first reflective layer RL1.

The second contact portion CNT2 may include a conductive material and may be electrically connected to a first semiconductor layer SCL1. The second contact portion CNT2 may electrically connect a power line (for example, ground power line (not shown)) included in the pixel circuit layer PCL and the first semiconductor layer SCL1.

The light emitting element LD may be disposed on the element base BS. The light emitting element LD may be disposed on the pixel circuit layer PCL (for example, the base layer BSL).

The light emitting element LD may be configured to emit light. According to an embodiment, the light emitting element LD may include an inorganic semiconductor material. For example, the light emitting element LD may include a semiconductor stacked member SSM. The semiconductor stacked member SSM may include the first semiconductor layer SCL1, a second semiconductor layer SCL2, and an active layer AL.

The first semiconductor layer SCL1 may include a semiconductor layer of a type different from that of the second semiconductor layer SCL2. For example, the first semiconductor layer SCL1 may include an N-type semiconductor. The first semiconductor layer SCL1 may include a GaN-based material. For example, the first semiconductor layer SCL1 may include one or more selected from a group of InAlGaN, GaN, AlGaN, and InGaN, and may include an N-type semiconductor layer doped with a first conductivity type dopant such as Si, Ge, and Sn.

The active layer AL may be disposed between the first semiconductor layer SCL1 and the second semiconductor layer SCL2. The active layer AL may include a single-quantum well or multi-quantum well structure.

The active layer AL may include a well layer and a barrier layer for forming a quantum well structure. For example, the active layer AL may include InGaN as the well layer, and the active layer AL may include GaN as the barrier layer.

The second semiconductor layer SCL2 may include a semiconductor layer of a type different from the first semiconductor layer SCL1. For example, the second semiconductor layer SCL2 may include a P-type semiconductor. The second semiconductor layer SCL2 may include a GaN-based material. For example, the second semiconductor layer SCL2 may include one or more selected from a group of InAlGaN, GaN, AlGaN, and InGaN, and may include a P-type semiconductor layer doped with a second conductivity type dopant such as Ga, B, and Mg.

According to an embodiment, the light emitting element LD may further include an electrode layer ELL and an insulating layer INF.

The electrode layer ELL may be disposed on the semiconductor stacked member SSM. According to an embodiment, the electrode layer ELL may be disposed in the light emitting element area LDA.

The electrode layer ELL may be electrically connected to the second semiconductor layer SCL2. The electrode layer ELL may be electrically connected to the first reflective layer RL. Accordingly, the semiconductor stacked member SSM may be electrically connected to the pixel circuit PXC through the electrode layer ELL and the first reflective layer RL.

An upper surface of the electrode layer ELL may be covered by the first reflective layer RL. According to an embodiment, the electrode layer ELL may be entirely covered by the first reflective layer RL in a plan view. According to an embodiment, a side surface of the electrode layer ELL may be covered by the first reflective layer RL, and another side surface of the electrode layer ELL may be exposed by the first reflective layer RL.

The electrode layer ELL may include a conductive material. For example, the electrode layer ELL may include indium tin oxide (ITO). However, the disclosure may not be limited thereto.

The insulating layer INF may be disposed on a side surface of the semiconductor stacked member SSM. For example, the insulating layer INF may cover side surfaces of each of the first semiconductor layer SCL1, the second semiconductor layer SCL2, and the active layer AL.

A portion of the insulating layer INF may be covered by the first reflective layer RL. Another portion of the insulating layer INF may be exposed by the first reflective layer RL.

The insulating layer INF may include an insulating material. For example, the insulating layer INF may include one or more of a group of silicon nitride (SiNₓ), silicon oxide (SiOₓ), silicon oxynitride (SiOₓN_{y}), and aluminum oxide (AlₓO_{y}). However, the disclosure may not be necessarily limited to the example described above.

The light emitting element LD may not overlap the second reflective layer QRL in a plan view. The light emitting element LD may be adjacent to the second reflective layer QRL in a planar direction (for example, a horizontal direction such as the first direction DR1, the second direction DR2 or a combination of the first and second directions DR1 and DR2). The light emitting element LD may overlap the first reflective layer RL in a plan view. The light emitting element LD may be adjacent to the first reflective layer RL in the planar direction (for example, the horizontal direction).

The light emitting element LD may be disposed in the light emitting element area LDA. The light emitting element LD may not be disposed in the sub-pixel area SPXA. The light emitting element LD may overlap the light blocking layer BM in a plan view. According to an embodiment, light of one color may not be visible in an area where the light emitting element LD is disposed. Accordingly, the light emitting element area LDA may be provided in a non-sub-pixel area NSPXA.

The light emitting element LD may be disposed between adjacent sub-pixel areas SPXA. For example, a sub-pixel area SPXA may be formed on a side of the light emitting element LD, and another sub-pixel area SPXA may be formed on another side of the light emitting element LD.

The first reflective layer RL may be disposed on the element base BS. The first reflective layer RL may overlap the light emitting element area LDA in a plan view. Accordingly, the first reflective layer RL may overlap the non-sub-pixel area NSPXA in a plan view. According to an embodiment, a portion of the first reflective layer RL may be disposed in the sub-pixel area SPXA.

The first reflective layer RL may be configured to reflect light. The first reflective layer RL may guide a movement path of light emitted from the light emitting element LD. The first reflective layer RL may recycle light in a light output direction.

The first reflective layer RL may include a reflective material. The first reflective layer RL may include at least one of various metal materials including gold (Au), silver (Ag), aluminum (Al), molybdenum (Mo), chromium (Cr), titanium (Ti), nickel (Ni), neodymium (Nd), copper (Cu), platinum (Pt), and the like, or may include an alloy thereof.

The first reflective layer RL may expose a portion of the light emitting element LD and may cover other portions of the light emitting element LD. For example, the first reflective layer RL may surround other surfaces of the light emitting element LD except for a surface of the light emitting element LD facing the adjacent sub-pixel area SPXA.

The first reflective layer RL may cover at least a portion of a side portion of the light emitting element LD. The first reflective layer RL may expose a portion of a side portion of the light emitting element LD. The first reflective layer RL may cover an upper portion (for example, an upper surface of the electrode layer ELL) of the light emitting element LD. The first reflective layer RL may include a reflective wall extending in a thickness direction of the element base BS (for example, a third direction DR3). The first reflective layer RL may include the reflective wall extending in a planar direction of the element base BS (for example, a plane defined based on the first direction DR1 and the second direction DR2).

According to an embodiment (refer to FIG. 6), the first reflective layer RL may include a non-uniform surface. According to an embodiment, a surface of the first reflective layer RL may have a step shape structure, a zigzag structure, or the like. For example, the first reflective layer RL may include a body portion BO and a protrusion PRU that are integral with each other. According to an embodiment, the protrusion PRU may form a structure that protrudes from the body portion BO. The protrusion PRU may include multiple protrusions, and the first reflective layer RL may form the non-uniform surface to diffusely reflect applied light. Accordingly, a light recycling effect of the first reflective layer RL may be further increased.

The second reflective layer QRL may be disposed on the element base BS. The second reflective layer QRL may be disposed in the sub-pixel area SPXA. The second reflective layer QRL may not be disposed in the light emitting element area LDA.

The second reflective layer QRL may be configured to reflect light. The second reflective layer QRL may guide the movement path of the light emitted from the light emitting element LD. The second reflective layer QRL may recycle light in the light output direction.

The second reflective layer QRL may include a reflective material. For example, the second reflective layer QRL may include at least one of various metal materials including gold (Au), silver (Ag), aluminum (Al), molybdenum (Mo), chromium (Cr), titanium (Ti), nickel (Ni), neodymium (Nd), copper (Cu), platinum (Pt), and the like, or may include an alloy thereof.

The second reflective layer QRL may include a reflective wall extending in the planar direction of the element base BS (for example, the plane defined based on the first direction DR1 and the second direction DR2). For example, the second reflective layer QRL may include a reflective surface facing the light output direction (for example, the third direction DR3) of the display device DD.

According to an embodiment, a minutely designed light guide structure may be formed in the sub-pixel portions SPXU adjacent to each other, and a display device DD with improved light efficiency may be provided.

For example (refer to FIG. 7), the sub-pixel portion SPXU may include a first sub-pixel portion SPXU1 and a second sub-pixel portion SPXU2 that may be adjacent (for example, directly adjacent) to each other in the planar direction. A light guide structure of the first sub-pixel portion SPXU1 may be described in conjunction with a partial structure of the second sub-pixel portion SPXU2.

The first sub-pixel portion SPXU1 may include the light emitting element area LDA and the sub-pixel area SPXA. As described above, since the light emitting element area LDA and the sub-pixel area SPXA may be disposed alternately along a direction, the light emitting element area LDA of the second sub-pixel portion SPXU2 may be disposed on a side of the sub-pixel area SPXA of the first sub-pixel area SPXU1. The light emitting element areas LDA may be disposed on both sides of the sub-pixel area SPXA of the first sub-pixel portion SPXU1. The light emitting element LD may be disposed in the light emitting element area LDA, and the first reflective layer RL1 may be disposed on a side portion of the light emitting element LD.

Accordingly, the first reflective layer RL surrounding the light emitting element LD of the first sub-pixel portion SPXU1 may guide the light emitted from the light emitting element LD of the first sub-pixel portion SPXU1 so that the light faces the sub-pixel area SPXA of the first sub-pixel portion SPXU1. The first reflective layer RL surrounding the light emitting element LD of the second sub-pixel portion SPXU2 may guide light facing the second sub-pixel portion SPXU2 in the sub-pixel area SPXA of the first sub-pixel portion SPXU1 so that the light faces the sub-pixel area SPXA of the first sub-pixel portion SPXU1.

The second reflective layer QRL included in the first sub-pixel portion SPXU1 may reflect light applied in the sub-pixel area SPXA in the light output direction (for example, the third direction DR3) of the display device DD.

Finally, in addition to a disposition structure of the light emitting element area LDA and the sub-pixel area SPXA, the first reflective layer RL1 and the second reflective layer QRL may patterned at a position to implement a light recycling structure, thereby providing the display device DD with a high light efficiency. Since the light emitting area visible from the outside may be defined based on the sub-pixel area SPXA, the light emitting area may be further expanded if desirable by controlling the area of the sub-pixel area SPXA.

The color conversion layer CCL may be disposed on the element base BS in an area where the light emitting element LD may not be disposed. The color conversion layer CCL may be disposed in the sub-pixel area SPXA. The color conversion layer CCL may overlap the light emitting element LD in the planar direction. The color conversion layer CCL may not be disposed in the light emitting element area LDA. The color conversion layer CCL may not overlap the light blocking layer BM in a plan view. The color conversion layer CCL may overlap the second reflective layer QRL in a plan view.

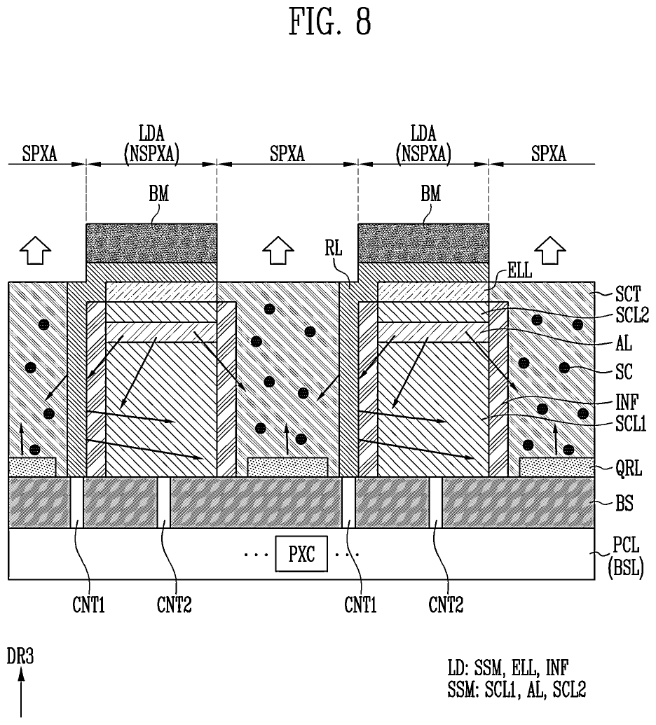

The color conversion layer CCL may be configured to change a wavelength of light. The color conversion layer CCL may include a first color conversion layer included in the first sub-pixel portion SPXU1 among the sub-pixel portions SPXU and a second color conversion layer included in the second sub-pixel portion SPXU2 among the sub-pixel portions SPXU. According to an embodiment, a scattering layer SCT including a scatterer SC (refer to FIG. 8) may be disposed in the sub-pixel area SPXA included in the third sub-pixel portion among the sub-pixel portions SPXU.

According to an embodiment, the light emitting elements of each of the sub-pixel portions SPXU may emit light of a same color (for example, the third color). At this time, as the color conversion layer CCL may be disposed in a portion of the sub-pixel portions SPXU, a full-color image may be displayed.

According to an embodiment, the color conversion layer CCL may include a quantum-dot QD that converts the light emitted from the light emitting element LD into light of a color. The quantum-dot QD may be dispersed in a matrix material such as a base resin and may produce the color conversion layer CCL.

According to an embodiment, the quantum-dot QD may include a first quantum-dot included in the first color conversion layer and a second quantum-dot included in the second color conversion layer. The first quantum-dot may absorb the light of the third color and shift a wavelength according to energy transition to emit the light of the first color. The second quantum-dot may absorb the light of the third color and shift the wavelength according to energy transition to emit the light of the second color.

The scattering layer SCT may be provided to efficiently use the light of the third color emitted from the light emitting element LD. According to an embodiment, the scattering layer SCT may include a scatterer SC and scatter applied light. The scatterer SCT may include various light scattering particles or light scattering materials. For example, the scatterer may include for example one or more of a group of silica (SiOₓ) (for example, a silica bead, hollow silica, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the disclosure may not be limited thereto.

According to an embodiment, the color conversion layer CCL may be adjacent to the light emitting element LD in the horizontal direction. The color conversion layer CCL may not overlap the light emitting element LD in a thickness direction (for example, the third direction DR3) of the element base BS, and an effect in which a thickness of the display device DD may be reduced may be provided.

In order to experimentally pattern the color conversion layer CCL, a bank structure in which the color conversion layer CCL may be accommodated may be separately required, but according to an embodiment, as the light emitting element LD and the first reflective layer RL may perform a bank role, and therefore a process step may be simplified.

The light blocking layer BM may be disposed on the first reflective layer RL. The light blocking layer BM may be disposed on the light emitting element LD. The light blocking layer BM may not overlap the sub-pixel area SPXA in a plan view. The light blocking layer BM may be disposed in the light emitting element area LDA.

The light blocking layer BM may overlap the first reflective layer RL in a plan view. The light blocking layer BM may not overlap the second reflective layer QRL in a plan view. The light blocking layer BM may not overlap the color conversion layer CCL in the planar direction.

The light blocking layer BM may prevent a color mixing defect visible from a front surface or a side surface of the display device DD. A material of the light blocking layer BM may not be particularly limited and may be configured of various light blocking materials. As an example, the light blocking layer BM may include a black matrix. However, the disclosure may not be limited thereto.

According to an embodiment, the light blocking layer BM may have a light blocking thickness BT. The light blocking thickness BT may be in a range of about 1 μm to about 5 μm. According to an embodiment, the light blocking thickness BT may be in a range of about 2 μm to about 4 μm. However, the disclosure may not be limited thereto.

According to an embodiment, the light blocking layer BM may not perform a bank role for accommodating the color conversion layer CCL. Accordingly, necessity for patterning the light blocking layer BM to have an excessive thickness may be reduced, and the light blocking layer BM may be manufactured to have the light blocking thickness BT described above.

Although not shown in the drawing, according to an embodiment, a capping layer capping the color conversion layer CCL and including an inorganic material may be further included. According to an embodiment, the display device DD may further include a color filter overlapping the sub-pixel area SPXA and may further include a window capable of transmitting light.

With reference to FIG. 8, a display device DD according to an embodiment is described. For convenience of description, a content that may overlap the content described above is briefly described or is not repeated.

FIG. 8 is a schematic diagram illustrating a display device according to an embodiment. FIG. 8 may show a schematic cross-sectional structure of the display device DD according to an embodiment. FIG. 8 may show a schematic cross-sectional structure corresponding to FIG. 5 of an embodiment described above.

The display device DD according to the embodiment may be different from the display device DD according to the embodiment described above, in that the scatterer SCT may be disposed in each of the sub-pixel areas SPXA without including the color conversion layer CCL.

According to an embodiment, the light emitting element LD may include a first light emitting element included in a first sub-pixel portion among the sub-pixel portions SPXU and configured to emit the light of the first color, a second light emitting element included in the second sub-pixel portion among the sub-pixel portions SPXU and configured to emit the light of the second color, and a third light emitting element included in the third sub-pixel portion among the sub-pixel portions SPXU and configured to emit the light of the third color. For example, each of the light emitting elements LD may be configured to emit the light of the first to third colors, and thus each of the light emitting elements LD may produce a self-emission element capable of implementing a full-color of image.

Accordingly, the scattering layer SCT including the scatterer SC may be disposed in the sub-pixel area SPXA of each of the sub-pixel portions SPXU. As described above, the scattering layer SCT may improve efficiency of the light emitted from the light emitting element LD.

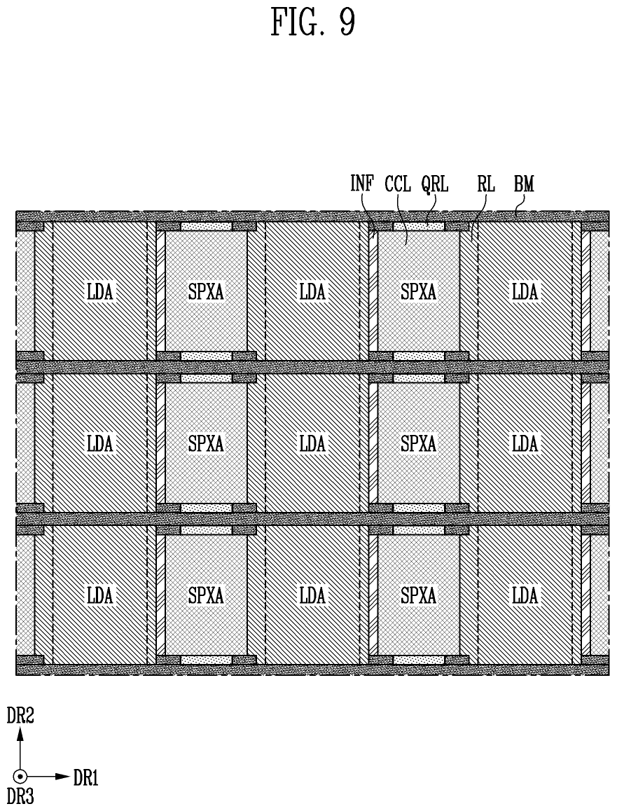

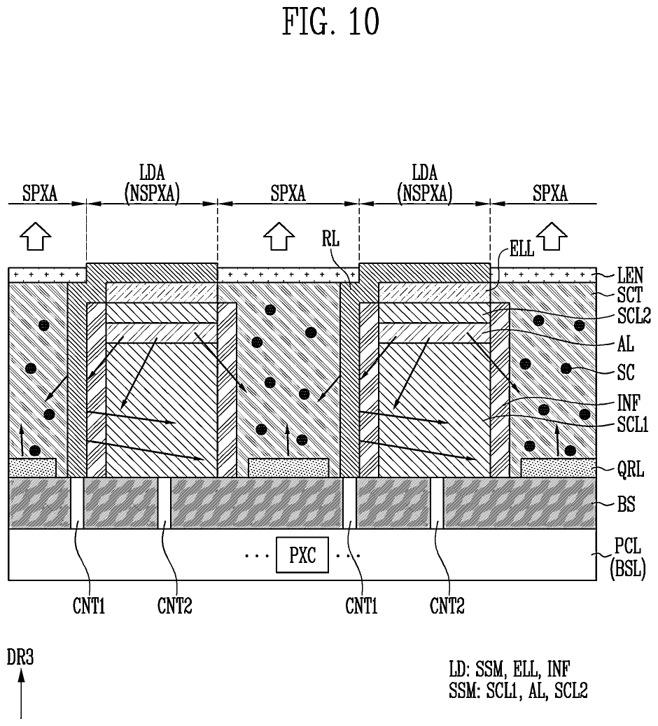

With reference to FIGS. 9 and 10, a display device DD according to an embodiment is described. For convenience of description, a content that may overlap the content described above is briefly described or may not be repeated.

FIGS. 9 and 10 are schematic diagrams illustrating a display device according to an embodiment. FIG. 9 may show a same area as the plan view described above with reference to FIGS. 2 and 3. FIG. 9 may show a plan view corresponding to FIG. 4 of the embodiment described above. FIG. 10 may show a schematic cross-sectional structure of the display device DD according to an embodiment. FIG. 10 may show a schematic cross-sectional structure corresponding to FIGS. 5 and 8 of the embodiment described above.

The display device DD according to the embodiment may be different from the display device DD according to the embodiment described above, in that the display device DD according to the embodiment does not include the light blocking layer BM.

For example, according to an embodiment, the light blocking layer BM may not be included. According to an embodiment, even though the light blocking layer BM is not included, an area other than the sub-pixel area SPXA in the display area DA may be covered by the first reflective layer RL, and thus the non-sub-pixel area SPXA may be defined. According to the embodiment, since a process step is simplified, a process cost may be reduced.

According to an embodiment, the display device DD may further include a lens part LEN. The lens part LEN may be disposed in the sub-pixel area SPXA. The lens part LEN may not be disposed in the light emitting element area LDA. The lens part LEN may overlap the second reflective layer QRL in a plan view. The lens part LEN may improve display quality by controlling an output path of light.

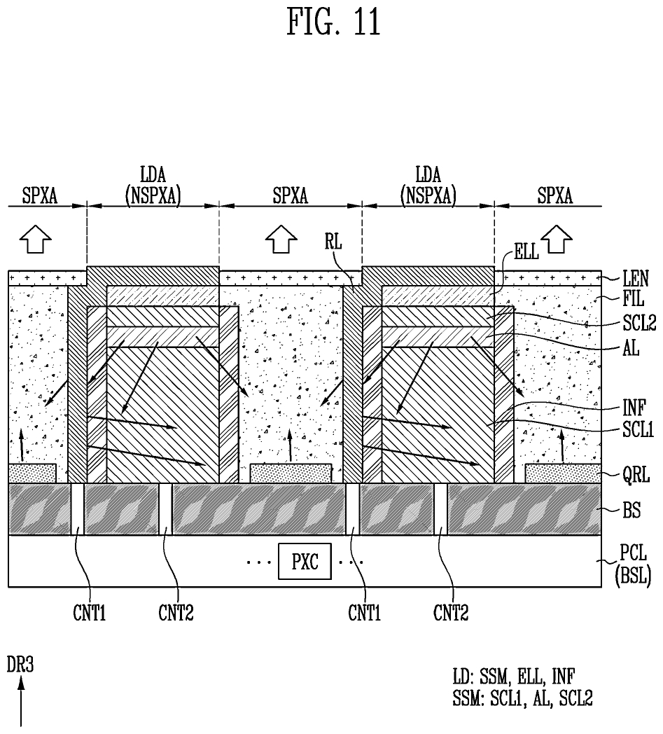

With reference to FIG. 11, a display device DD according to an embodiment is described. For convenience of description, a content that may overlap the content described above is briefly described or is not repeated.

FIG. 11 is a schematic diagram illustrating a display device according to an embodiment. FIG. 11 may show a schematic cross-sectional structure of the display device DD according to an embodiment. FIG. 11 may show a schematic cross-sectional structure corresponding to FIGS. 5, 8, and 10 of the embodiment described above.

The display device DD according to the embodiment is different from the display device DD according to the embodiment described above, in that a filling layer FIL may be disposed in an area corresponding to the color conversion layer CCL or the scattering layer SCT.

The filling layer FIL may be disposed in the sub-pixel area SPXA. The filling layer FIL may not be disposed in the light emitting element area LDA. The filling layer FIL may overlap the second reflective layer QRL in a plan view. The filling layer FIL may fill an area between the light emitting elements LD.

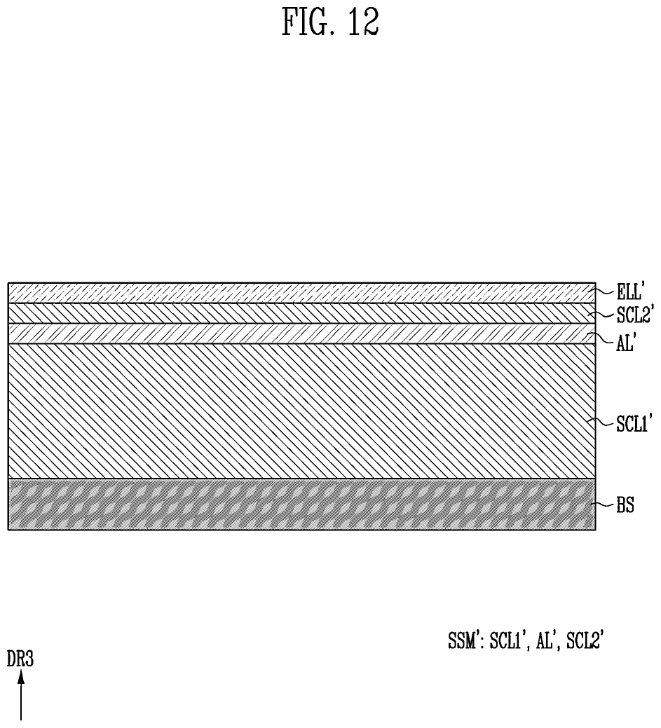

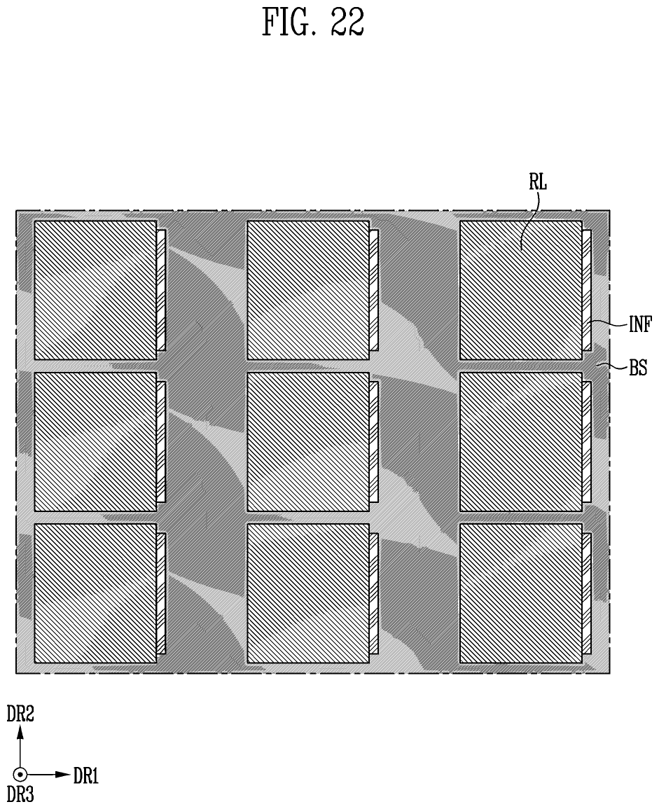

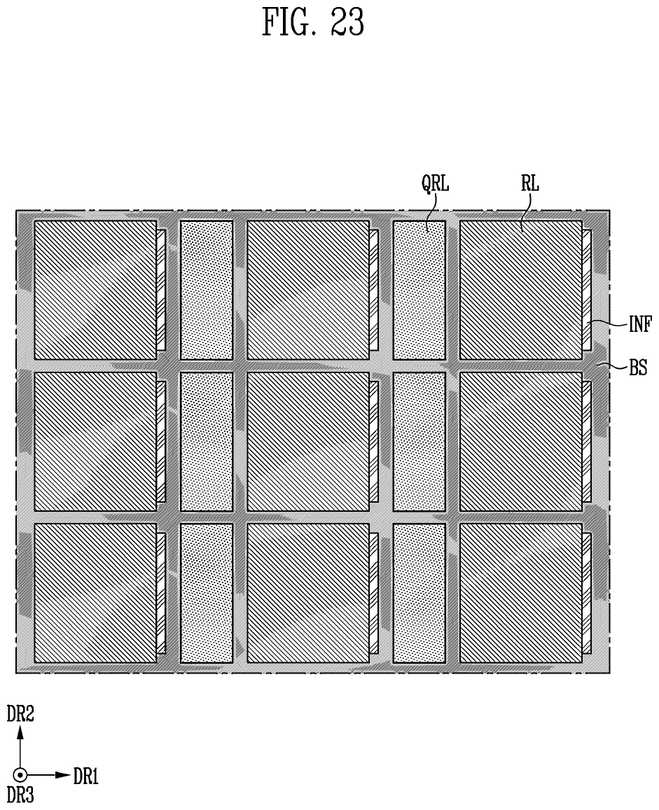

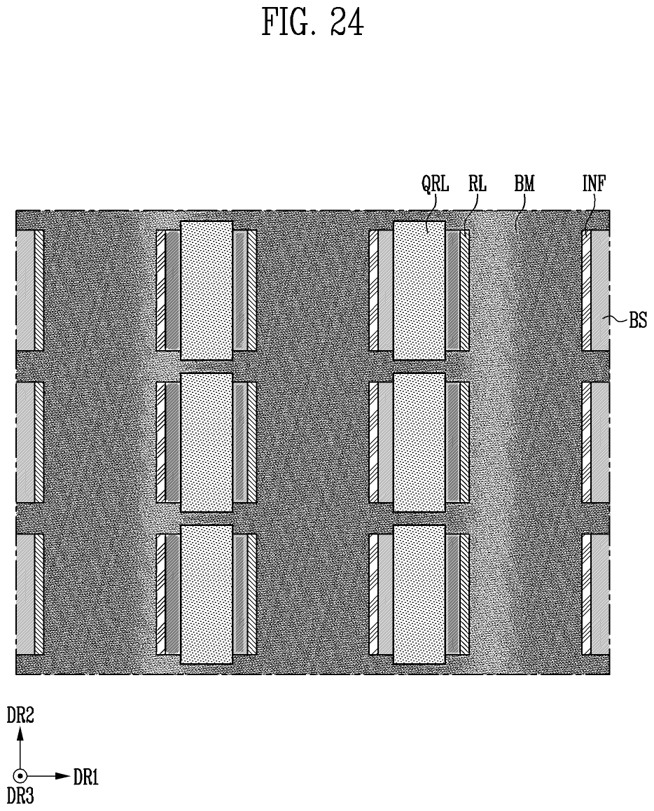

A method of manufacturing a display device according to an embodiment is described with reference to FIGS. 12 to 25. For convenience of description, a content that may overlap the content described above is briefly described or is not repeated.

For convenience of description, a manufacturing method of the display device DD according to the embodiment described above with reference to FIGS. 4 to 7 is described, and a technical feature of some modified embodiments is additionally described.

FIGS. 12 to 25 are schematic diagrams for each process step illustrating a method of manufacturing a display device according to an embodiment.

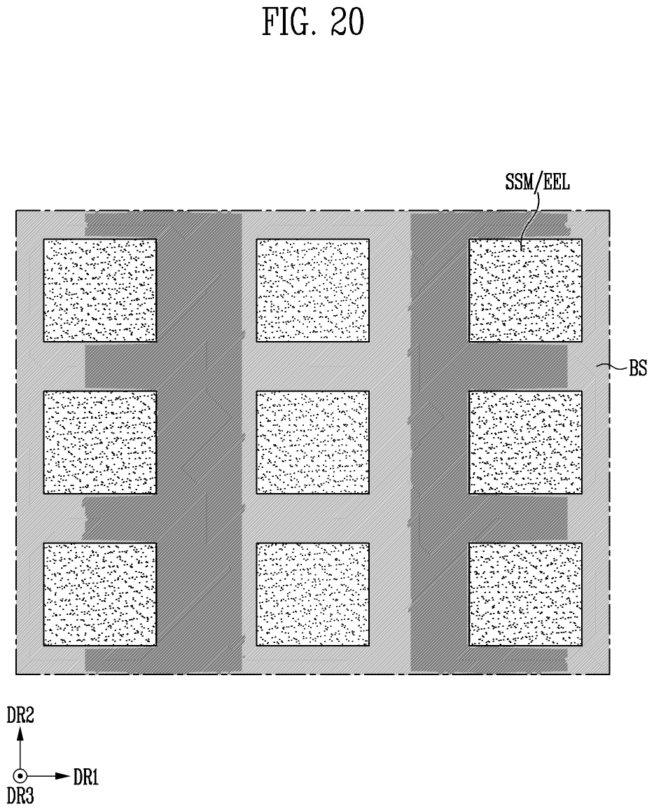

FIGS. 12 to 19 may be schematic cross-sectional views for each process step illustrating a method of manufacturing the display device DD according to an embodiment. FIGS. 20 to 25 may be schematic plan views for each process step illustrating a method of manufacturing the display device DD according to an embodiment. In other words, FIGS. 20-25 may be coextensive in the manufacturing process with FIGS. 12-19, but show a top or a plan view as opposed to the schematic cross-sectional views of FIGS. 12-19 of various steps in the manufacturing process.

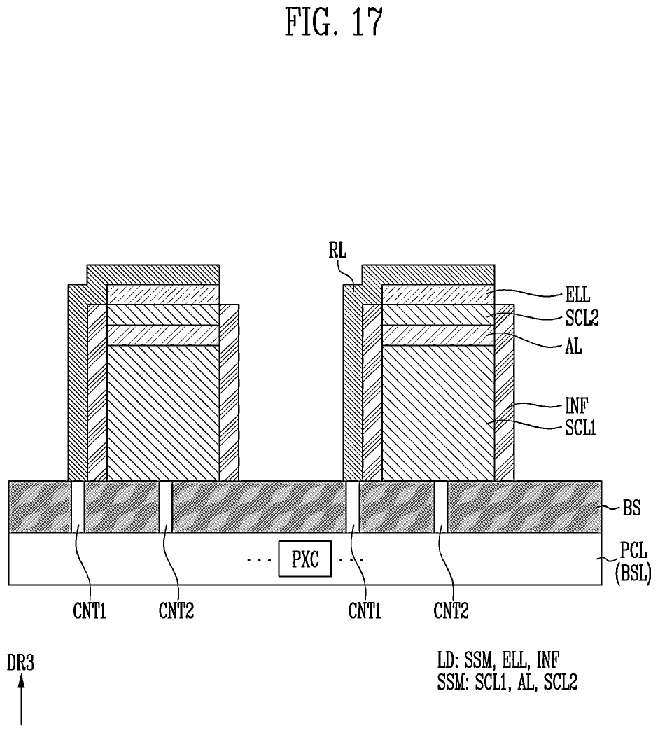

FIGS. 12 to 16 and FIGS. 20 to 22 may illustrate steps before the light emitting elements LD are disposed on the pixel circuit layer PCL (for example, the base layer BSL). FIGS. 17 to 19 and FIGS. 23 to 25 may illustrate steps after the light emitting elements LD are disposed on the pixel circuit layer PCL (for example, the base layer BSL).

Referring to FIG. 12, a base semiconductor stacked member SSM′ and a base electrode ELL′ may be formed on the element base BS. For example, semiconductor materials may be sequentially formed on the element base BS. The base semiconductor stacked member SSM′ may include a first base semiconductor layer SCL1′, a base active layer AL′, and a second base semiconductor layer SCL2′.

The element base BS may be a base plate for growing an object material. For example, the element base BS may be a wafer for epitaxial growth of a material. The element base BS may be a sapphire substrate and may include aluminum oxide (AlOₓ). However, the disclosure may not be limited thereto.

In the step, a first base semiconductor layer SCL1′, a base active layer AL′, and a second base semiconductor layer SCL2′ may be sequentially formed (for example, epitaxially grown) on the element base BS.

The first base semiconductor layer SCL1′ may include a material for forming the first semiconductor layer SCL1. The base active layer AL′ may include a material for forming the active layer AL. The second base semiconductor layer SCL2′ may include a material for forming the second semiconductor layer SCL2.

In the step, the base electrode ELL′ may be formed (for example, deposited) on the second base semiconductor layer SCL2′. The base electrode ELL′ may include a material for forming the electrode layer ELL, and may be formed through a process such as sputtering. However, the disclosure may not be limited thereto.

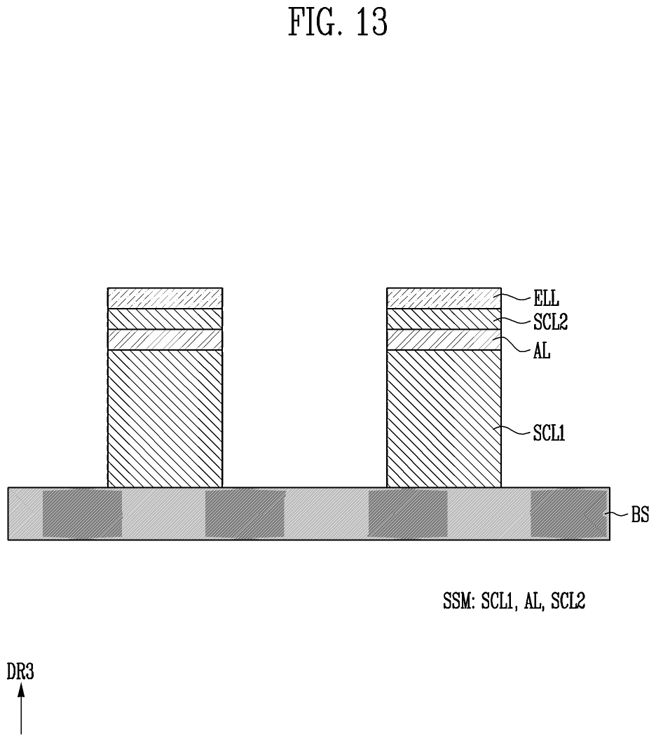

Referring to FIGS. 13 and 20, the base electrode ELL′ and the base semiconductor stacked member SSM′ may be etched.

In the step, at least a portion of the base electrode ELL′ may be etched (for example, dry etched) to produce the electrode layer ELL. In the step, at least a portion of the base semiconductor stacked member SSM′ may be etched (for example, dry etched) to produce the semiconductor stacked member SSM.

Accordingly, the first semiconductor layer SCL1, the active layer AL, the second semiconductor layer SCL2, and the electrode layer ELL may be sequentially stacked, and each side portion may be exposed. Each of the semiconductor stacked members SSM and the electrode layers ELL may form a portion of each of the light emitting elements LD.

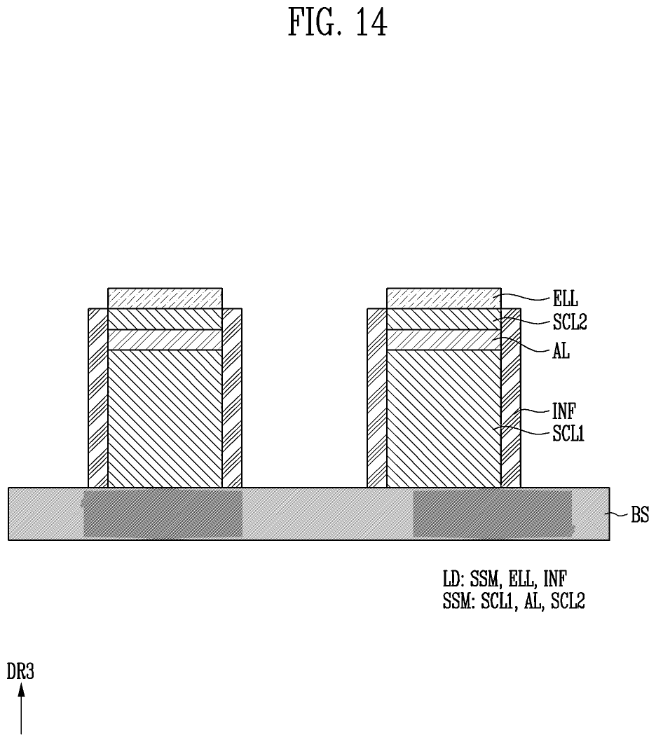

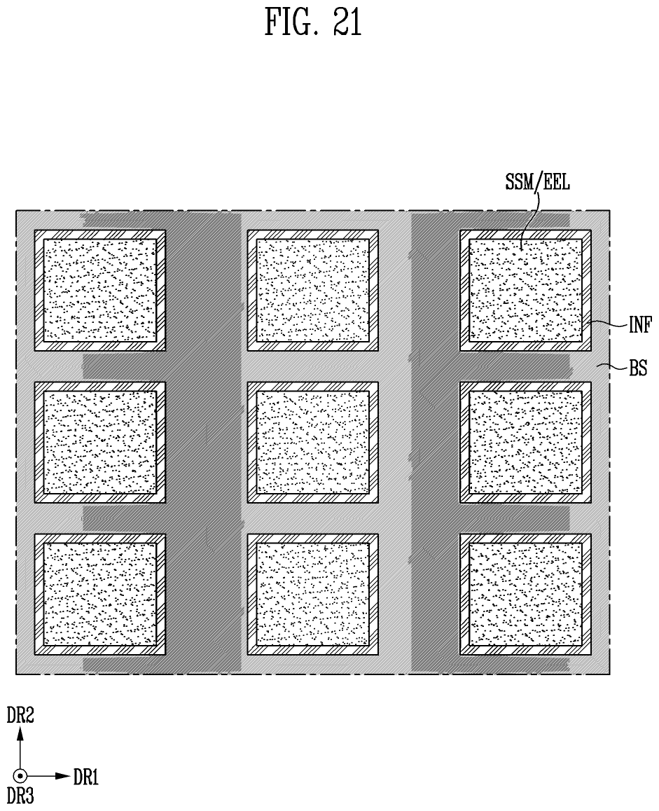

Referring to FIGS. 14 and 21, the insulating layer INF may be patterned to cover at least a portion (for example, a side portion) of the semiconductor stacked member SSM and expose at least a portion the electrode layer ELL.

For example, the insulating layer INF may be formed (or deposited) by various methods and may be etched (for example, wet etched). For example, in order to deposit the insulating layer INF, a physical vapor deposition (PVD) process, a chemical vapor deposition (CVD) process, or the like may be used. However, the disclosure may not be limited thereto.

Accordingly, the light emitting element LD including the insulating layer INF, the electrode layer ELL, and the semiconductor stacked member SSM may be prepared.

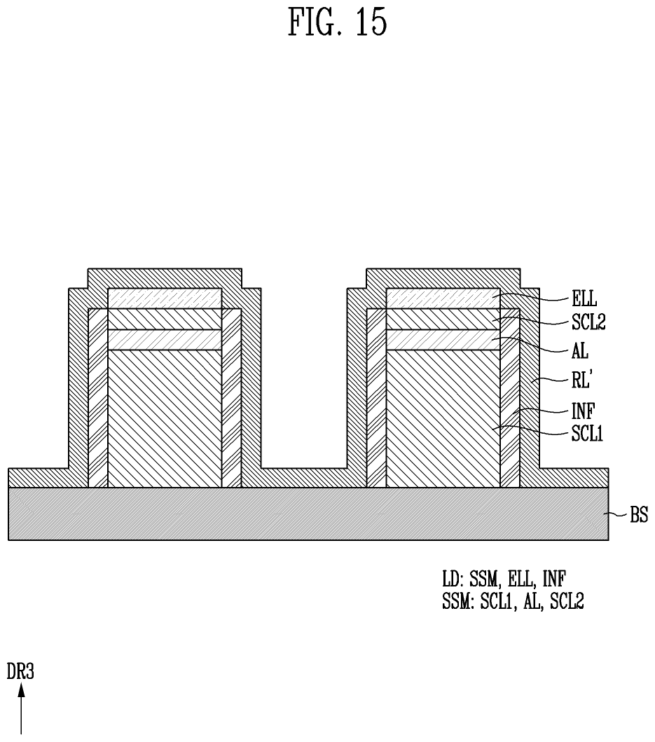

Referring to FIGS. 15, 16, and 22, a base reflective layer RL′ for forming the first reflective layer RL may be formed (for example, deposited).

In order to deposit the first base reflective layer RL′, a PVD process, a CVD process, or the like may be used. However, the disclosure is not limited thereto.

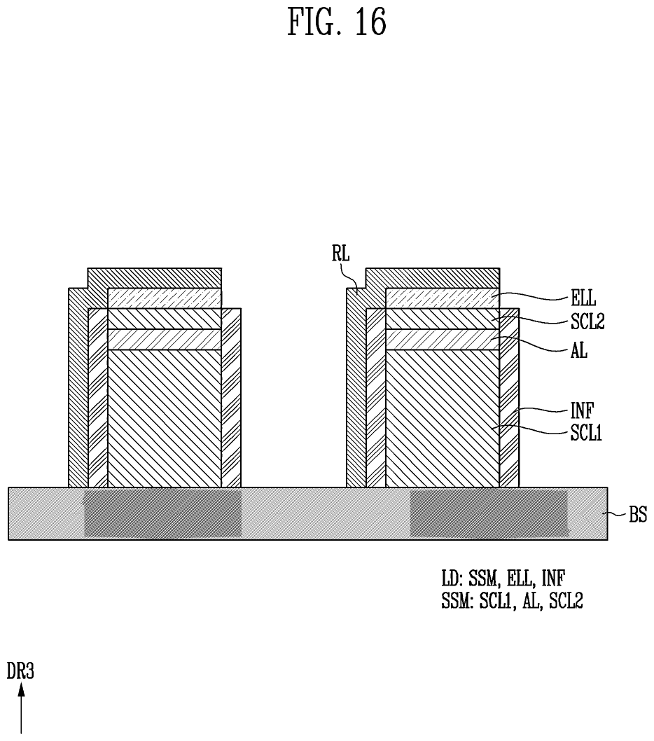

At the formation of the first base reflective layer RL′ step, the first base reflective layer RL′ may cover the entire surface of the light emitting element LD. At least a portion of the first base reflective layer RL′ may be etched (for example, dry etched), and the first reflective layer RL exposing at least a portion of the light emitting element LD as in FIG. 16 may be produced. For example, the first reflective layer RL may expose a side of the light emitting element LD. Accordingly, as described above, a path through which the light emitted from the light emitting element LD propagates may be formed.

Referring to FIG. 17, the light emitting element LD and the element base BS may be disposed on the pixel circuit layer PCL.

According to an embodiment, in order to dispose the light emitting element LD on the pixel circuit layer PCL, a transfer process of a wafer to wafer method may be performed.

A process (for example, a laser lift off process or the like) of separating the light emitting element LD from a wafer (for example, the element base BS) for manufacturing the light emitting element LD may not be performed. Accordingly, a process step may be simplified, a process cost may be reduced, and element stability may be improved.

For example, in a state in which the light emitting element LD is disposed on the element base BS, the light emitting element LD may be disposed on the pixel circuit layer PCL. According to an embodiment, the first contact portion CNT1 and the second contact portion CNT2 may be formed in the element base BS, and the element base BS may be disposed on the pixel circuit layer PCL including the base layer BSL and the pixel circuit PXC.

At the disposing of the light emitting element LD on the pixel circuit layer PCL step, the first reflective layer RL may be electrically connected to the pixel circuit PXC through the first contact portion CNT1. Although not shown in the drawing, the first semiconductor layer SCL1 may be electrically connected to a power line formed in the pixel circuit layer PCL through the second contact portion CNT2.

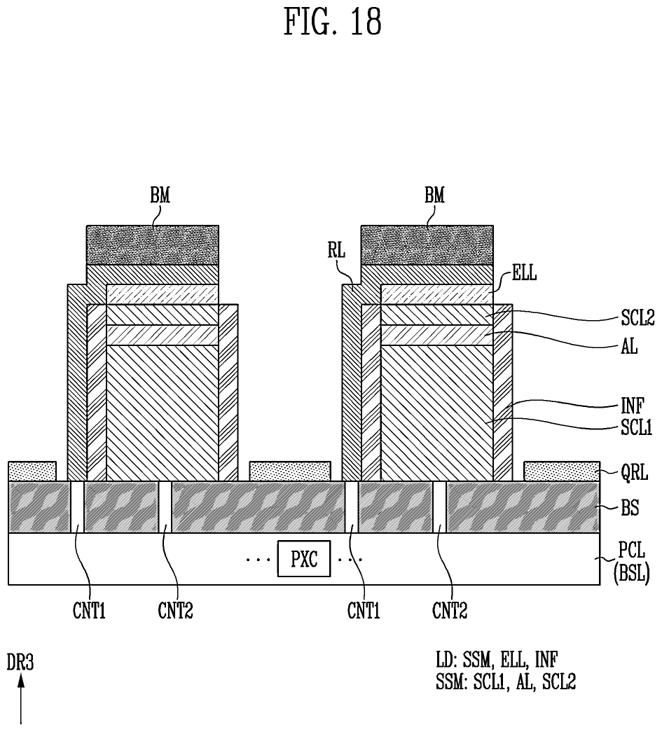

Referring to FIGS. 18, 23, and 24, the second reflective layer QRL and the light blocking layer BM may be patterned.

For example, the second reflective layer QRL may be disposed between areas where adjacent light emitting elements LD are disposed. The second reflective layer QRL may be disposed between adjacent first reflective layers RL. The light blocking layer BM may be patterned to overlap the area where the light emitting elements LD are disposed.

According to an embodiment, a process of patterning the light blocking layer BM may be omitted. Since the first reflective layer RL may cover an upper surface of the light emitting element LD, the non-sub-pixel area NSPXA may be defined.

According to an embodiment, an order of a process step of patterning the second reflective layer QRL and a process step of patterning the light blocking layer BM may not be particularly limited.

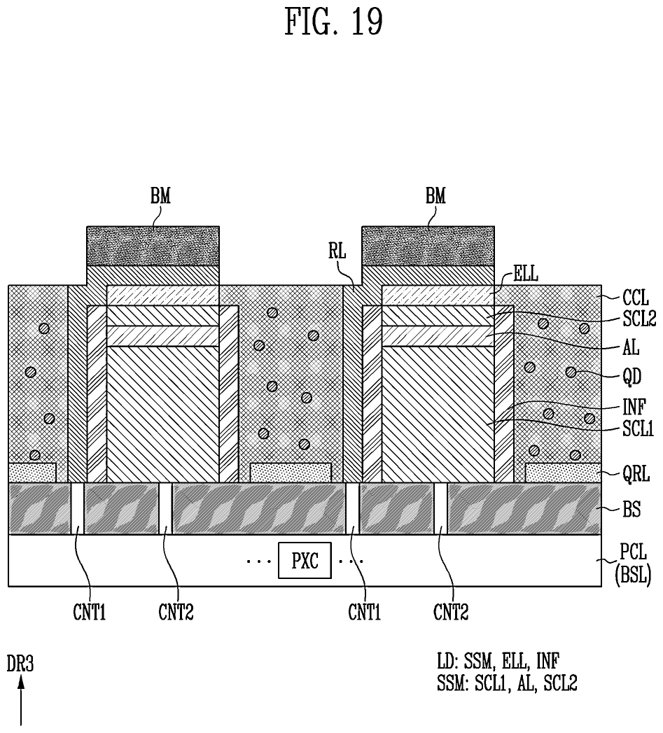

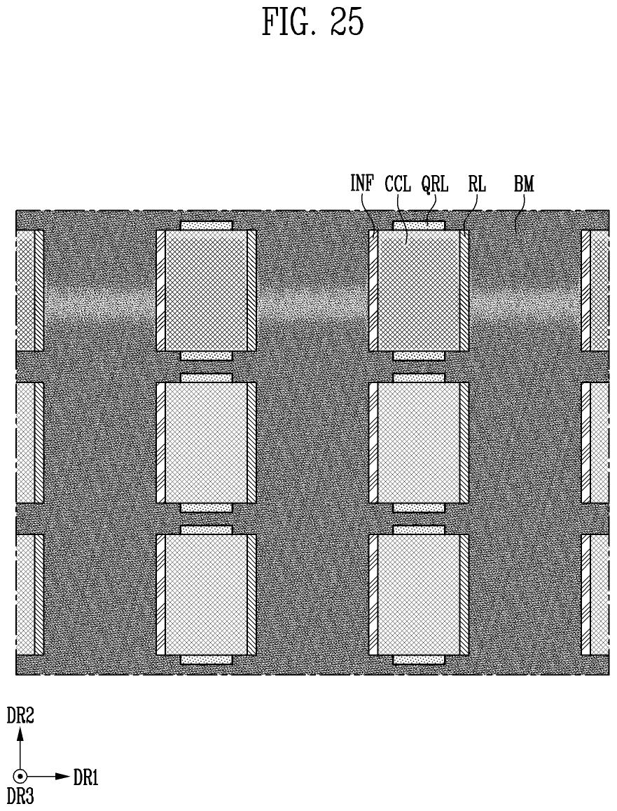

Referring to FIGS. 19 and 25, the color conversion layer CCL may be patterned. According to an embodiment, the color conversion layer CCL may be patterned by a typical photolithography process or the like. However, the disclosure may not be limited thereto.

In the step, the color conversion layer CCL may be disposed between areas where adjacent light emitting elements LD are disposed. The color conversion layer CCL may be disposed between adjacent first reflective layers RL. For example, when the color conversion layer CCL is patterned, the light emitting element LD and the first reflective layer RL may function as a bank structure for accommodating the color conversion layer CCL.

According to an embodiment, as described above, the scattering layer SCT may be disposed between the areas where the light emitting elements LD may not be disposed, or according to an embodiment, the filling layer FIL may be disposed in place of the color conversion layer CCL. According to an embodiment, a process of patterning the lens part LEN may be further performed.

Thereafter, according to an embodiment, a process of disposing the window or the like may be further performed, and the display device DD according to an embodiment may be prepared.

As described above, although the disclosure has been described with reference to the embodiment, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims.

What is claimed is:

1. A display device comprising:
a sub-pixel portion disposed on a base layer and including a light emitting element area where a light emitting element is disposed and a sub-pixel area,
wherein the light emitting element area and the sub-pixel area do not overlap each other in a plan view.

2. The display device according to claim 1, wherein the light emitting element area is a non-sub-pixel area where light of a color is not visible.

3. The display device according to claim 1, wherein the light emitting element area and the sub-pixel area are arranged alternately along a direction.

4. The display device according to claim 1, wherein the sub-pixel portion has a rectangular shape including a long side and a short side in a plan view.

5. The display device according to claim 1, further comprising:
a first reflective layer covering at least a portion of the light emitting element and exposing a side portion of the light emitting element,
wherein the first reflective layer overlaps the light emitting element area in a plan view.

6. The display device according to claim 5, wherein the side portion of the light emitting element exposed by the first reflective layer faces the sub-pixel area.

7. The display device according to claim 5, wherein
the first reflective layer includes a plurality of protrusions and a body portion that are integral with each other, and
each of the protrusions forms a protruding structure that protrudes from the body portion.

8. The display device according to claim 5, further comprising:
a pixel circuit layer including the base layer and a pixel circuit disposed on the base layer; and
an element base disposed on the pixel circuit layer, the element base forming a base on which the light emitting element is disposed, the element base including a contact portion.

9. The display device according to claim 8, wherein the first reflective layer is electrically connected to the light emitting element and is electrically connected to the pixel circuit through the contact portion.

10. The display device according to claim 5, further comprising:
a second reflective layer disposed in the sub-pixel area, the second reflective layer does not overlap the light emitting element in a plan view.

11. The display device according to claim 10, wherein the second reflective layer includes a reflective surface facing a light output direction of the display device.

12. The display device according to claim 10, further comprising:
a color conversion layer disposed on the second reflective layer in the sub-pixel area and including a quantum-dot,
wherein the color conversion layer is adjacent to the light emitting element in a planar direction.

13. The display device according to claim 1, further comprising:
a light blocking layer disposed on the light emitting element, the light blocking layer does not overlap the sub-pixel area.

14. The display device according to claim 1, wherein
the sub-pixel portion includes a first sub-pixel portion and a second sub-pixel portion disposed adjacent to each other in a planar direction,
each of the first sub-pixel portion and the second sub-pixel portion comprises:
a first reflective layer covering at least a side portion of the light emitting element; and
a second reflective layer disposed in the sub-pixel area, and
light emitted by the light emitting element included in the first sub-pixel portion is guided in a light output direction of the display device by the first reflective layer of the first sub-pixel portion, the first reflective layer of the second sub-pixel portion, and the second reflective layer of the first sub-pixel portion.

15. The display device according to claim 1, wherein
the sub-pixel portion includes a first sub-pixel portion emitting light of a first color, a second sub-pixel portion emitting light of a second color, and a third sub-pixel portion emitting light of a third color,
a first color conversion layer including a first quantum-dot is disposed in the sub-pixel area of the first sub-pixel portion,
a second color conversion layer including a second quantum-dot is disposed in the sub-pixel area of the second sub-pixel portion, and
a scattering layer including a scatterer is disposed in the sub-pixel area of the third sub-pixel portion.

16. The display device according to claim 1, wherein
the sub-pixel portion includes a first sub-pixel portion emitting light of a first color, a second sub-pixel portion emitting light of a second color, and a third sub-pixel portion emitting light of a third color,
the light emitting element of the first sub-pixel portion is a first light emitting element emitting the light of the first color,
the light emitting element of the second sub-pixel portion is a second light emitting element emitting the light of the second color,
the light emitting element of the third sub-pixel portion is a third light emitting element emitting the light of the third color, and
a scattering layer including a scatterer is disposed in the sub-pixel area of each of the first sub-pixel portion, the second sub-pixel portion, and the third sub-pixel portion.

17. A display device comprising:
a light emitting element disposed on a base layer and in a light emitting element area;
a first reflective layer covering at least a portion of the light emitting element and exposing at least another portion of the light emitting element;
a second reflective layer disposed in a sub-pixel area, the sub-pixel area being adjacent to and in a planar direction from the light emitting element area, and the second reflective layer including a reflective surface facing a light output direction of the display device; and
a color conversion layer disposed in the sub-pixel area, the color conversion layer including a quantum-dot and overlapping the second reflective layer in a plan view.

18. A method of manufacturing a display device, the method comprising:
manufacturing a light emitting element on an element base; and
disposing the element base and the light emitting element on a pixel circuit layer, wherein the manufacturing of the light emitting element comprises:
patterning the light emitting element on the element base;
patterning a first reflective layer covering a portion of the light emitting element and exposing at least another portion of the light emitting element; and
patterning a second reflective layer in an area where the light emitting element is not disposed.

19. The method according to claim 18, wherein
the element base includes a wafer for forming the light emitting element,
the pixel circuit layer includes a pixel circuit, and
the disposing of the element base and the light emitting element on the pixel circuit layer comprises forming a contact portion through the element base to electrically connect the pixel circuit to the light emitting element.

20. The method according to claim 18, further comprising:
forming a color conversion layer including a quantum-dot on the element base in an area where the light emitting element is not disposed,
wherein the light emitting element and the first reflective layer form a bank structure for the forming of the color conversion layer.
